(19) United States
(12) Patent Application Publication
(10) Pub. No.: US 2017/0069792 A1
(43) Pub. Date: Mar. 9, 2017

(54) SEMICONDUCTOR LIGHT EMITTING DEVICE

(71) Applicant: KABUSHIKI KAISHA TOSHIBA, Tokyo (JP)

(72) Inventor: Kyohei SHIBATA, Kanazawa Ishikawa (JP)

(21) Appl. No.: 15/055,365

(22) Filed: Feb. 26, 2016

(30) Foreign Application Priority Data
Sep. 9, 2015 (JP) 2015-177258

(51) Int. Cl. H01L 33/22; H01L 33/62; H01L 33/40; H01L 33/06; H01L 33/32

(52) U.S. Cl. CPC H01L 33/22; H01L 33/06; H01L 33/32; H01L 33/405; H01L 33/62

(57) ABSTRACT

According to one embodiment, a semiconductor light emitting device includes a substrate that has a surface on which a recessed portion is provided, a light emitting body that is provided on the surface of the substrate, and a first metal layer between the light emitting body and the substrate, and contacts an inner surface of the recessed portion. The light emitting body includes a first semiconductor layer of a first conductivity type, a second semiconductor layer of a second conductivity type, and a light emitting layer between the first semiconductor layer and the second semiconductor layer.

### CROSS-REFERENCE TO RELATED APPLICATION

This application is based upon and claims the benefit of priority from Japanese Patent Application No. 2015-177258, filed Sep. 9, 2015, the entire contents of which are incorporated herein by reference.

### FIELD

Exemplary embodiments described herein relate to a semiconductor light emitting device.

### BACKGROUND

Semiconductor light emitting devices are formed by forming a semiconductor including a light emitting layer on a first substrate, and then moving the semiconductor onto a second substrate which is separated from the first substrate. The semiconductor layer and the second substrate are bonded to each other via, for example, a metal layer. However, there is a concern that a layer structure which is formed of different materials will have distortion occurring in the inside thereof, and thus reliability of the semiconductor light emitting device is deteriorated.

### DESCRIPTION OF THE DRAWINGS

FIGS. 1A and 1B are sectional views schematically illustrating a semiconductor light emitting device according to a first embodiment.

FIGS. 2A and 2B are sectional views schematically illustrating manufacturing processes of the semiconductor light emitting device according to the first embodiment.

FIGS. 3A and 3B are sectional views schematically illustrating the manufacturing processes following FIGS. 2A and 2B.

FIGS. 4A and 4B are sectional views schematically illustrating the manufacturing processes following FIGS. 3A and 3B.

FIGS. 5A and 5B are sectional views schematically illustrating the manufacturing processes following FIGS. 4A and 4B.

FIGS. 6A and 6B are sectional views schematically illustrating a surface of a substrate according to the first embodiment.

FIG. 7 is a sectional view schematically illustrating a semiconductor light emitting device according to a second embodiment.

### DETAILED DESCRIPTION

In general, according to one embodiment, there is provided a semiconductor light emitting device including a substrate that has a surface in which a recessed portion is formed, a light emitting body on the surface of the substrate and including a first semiconductor layer of a first conductivity type, a second semiconductor layer of a second conductivity type, and a light emitting layer between the first semiconductor layer and the second semiconductor layer, and a first metal layer between the light emitting body and the surface of the substrate and contacting an inner surface of the recessed portion.

Hereinafter, the embodiment will be described with reference to the drawings. The same components in the drawings are given the same reference numerals, and the description will focus on the different components and the specific description of the same reference numerals will be omitted. In addition, the drawings are schematic or conceptual, and thus the relationship between the thickness and the width of each portion, and the size ratio between portions are not necessarily the same as reality. Moreover, even when representing the same components, dimensions and ratios are expressed differently depending on the drawings in some cases.

Further, an arrangement and structure of each component will be described by using an X-axis, a Y-axis, and a Z-axis which are shown in the drawings. The X-axis, the Y-axis, and the Z-axis are perpendicular to each other, and respectively represent an X-direction, a Y-direction, and a Z-direction. In addition, in some cases the Z-direction indicates an upper direction, and a direction opposite to the Z-direction indicates a lower direction.

The description of embodiments is illustrative, and the disclosure is not necessarily limited thereto. Also, configuring components described in the respective embodiments can be commonly used as long as being technically possible.

### First Embodiment

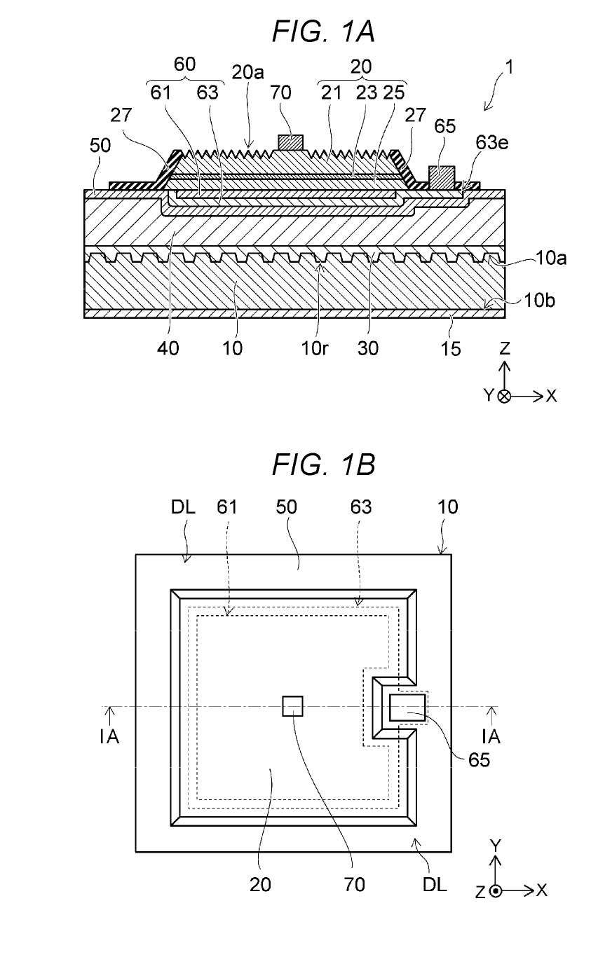

FIGS. 1A and 1B are sectional views schematically illustrating a semiconductor light emitting device 1 according to the first embodiment. FIG. 1A is a sectional view taken along line IA-IA shown in FIG. 1B. FIG. 1B is a top view.

As illustrated in FIG. 1A, the semiconductor light emitting device 1 includes a substrate 10 and a light emitting body 20. The light emitting body 20 is provided on the substrate 10.

The substrate 10 is, for example, a conductive silicon substrate. The substrate 10 includes a recessed portion 10r formed in a surface 10a thereof. The recessed portion 10r is provided in such a manner that an average depth thereof is in a range of from 0.01 μm to 2 μm.

The light emitting body 20 includes a first semiconductor layer 21, which may be an n-type semiconductor layer, a light emitting layer 23, and a second semiconductor layer 25, which may be a p-type semiconductor layer. The light emitting layer 23 is provided between the first semiconductor layer 21 and the second semiconductor layer 25. A top surface 20a of the light emitting body 20 may be roughened so as to improve the efficiency of light extraction.

The semiconductor light emitting device 1 is provided with a first metal layer 30, a second metal layer 40, and a third metal layer 50 between the substrate 10 and the light emitting body 20. The first metal layer 30 is provided to cover the surface 10a of the substrate 10 and an inner surface of the recessed portion 10r, and to come into contact with the inner surface of the recessed portion 10r. For example, a portion of the first metal layer 30 may be embedded into the recessed portion 10r. The second metal layer 40 is provided on the first metal layer 30. The third metal layer 50 is provided between the second metal layer 40 and the light emitting body 20.

The first and third metal layers 30 and 50 may include titanium (Ti), a titanium nitride (TiN), platinum (Pt), and nickel (Ni). The second metal layer 40 contains a material having a melting point which is lower than those of the first and third metal layers 30 and 50. The second metal layer 40 may contain a bonding metal such as a solder material. The first and third metal layers 30 and 50 serve as barrier metal which prevents metal atoms included in the second metal layer 40 from being diffused.

The semiconductor light emitting device 1 is further provided with a first electrode 60, a bonding pad 65, and a second electrode 70. The first electrode 60 is provided between the light emitting body 20 and the third metal layer 50.

The first electrode 60 includes a contact layer 61 and a cap layer 63. The contact layer 61 comes into contact with the second semiconductor layer 25, and is electrically connected to the second semiconductor layer 25. The cap layer 63 covers the contact layer 61 on the second semiconductor layer 25. The contact layer 61 and the cap layer 63 contain a material such as silver or aluminum which reflects light radiated (emitted) from the light emitting layer 23.

The cap layer 63 includes an extending portion 63e which extends to a periphery of the light emitting body 20 along the surface of the third metal layer 50. The bonding pad 65 is provided on the extending portion 63e. The bonding pad 65 connects the first electrode 60 to an outside circuit, for example, via a metal wire.

The second electrode 70 is provided on the first semiconductor layer 21, and is electrically connected to the first semiconductor layer 21. The second electrode 70 serves as a bonding pad, for example.

The semiconductor light emitting device 1 further includes a fourth metal layer 15 and a passivation film 27. The fourth metal layer 15 comes into contact with and is electrically connected to the rear surface 10b of the substrate 10. The fourth metal layer 15 is connected to a solder material or the like when the semiconductor light emitting device 1 is mounted on, for example, the mount substrate. Owing to this configuration, it is possible to efficiently dissipate heat generated in the light emitting body 20. The passivation film 27 covers a side surface of the light emitting body 20 and protects an end surface of the light emitting layer 23. The passivation film 27 is, for example, a silicon oxide film.

As illustrated in FIG. 1B, the semiconductor light emitting device 1 may be formed into a square shape. A dicing line DL is drawn around the light emitting body 20. The third metal layer 50 is exposed along the dicing line DL. In addition, the contact layer 61 is positioned in the cap layer 63 in X-Y plane.

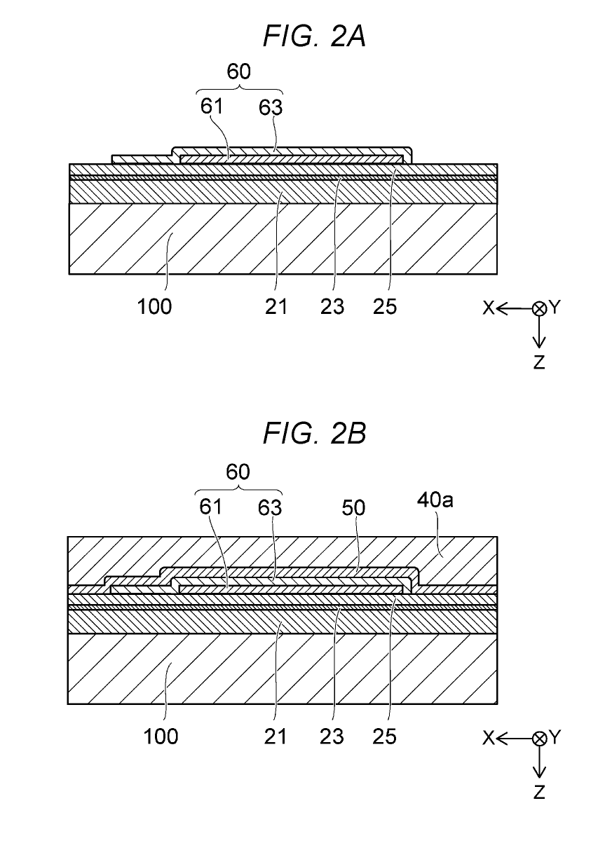

Next, a manufacturing method of the semiconductor light emitting device 1 according to the first embodiment will be described with reference to FIG. 2A to FIG. 5B. FIG. 2A to FIG. 5B are schematic sectional views sequentially illustrating manufacturing processes of the semiconductor light emitting device 1.

As illustrated in FIG. 2A, the first semiconductor layer 21, the light emitting layer 23, and the second semiconductor layer 25 are formed on the substrate 100 by performing epitaxial growth. The substrate 100 may be a silicon substrate. The first semiconductor layer 21, the light emitting layer 23, and the second semiconductor layer 25 may be formed using a metal organic chemical vapor deposition (MOCVD) method, which is performed by using organic metal as a raw material.

The first semiconductor layer 21 may include an n-type gallium nitride layer (a GaN layer). In addition, the first semiconductor layer 21 may further include a buffer layer including GaN, aluminum nitride (AlN), aluminum gallium nitride (AlGaN), and the like. The buffer layer is provided between the substrate 100 and the n-type GaN layer.

The light emitting layer 23 includes a quantum well which is configured to include, for example, a well layer which is formed of indium gallium nitride (InGaN), and a barrier layer which is formed of GaN. In addition, the light emitting layer 23 may include a multiple quantum well structure which includes a plurality of quantum wells.

The second semiconductor layer 25 may have a structure in which a p-type AlGaN layer and a p-type GaN layer are stacked, for example. In such a structure, the p-type AlGaN layer is formed on the light emitting layer 23, and the p-type GaN layer is formed on the p-type AlGaN layer.

Further, the first electrode 60 is formed on the second semiconductor layer 25. The first electrode 60 includes the contact layer 61 and the cap layer 63. The contact layer 61 is selectively formed on the second semiconductor layer 25. The contact layer 61 may be a metal layer which includes silver. Here, the expression “selectively formed” means the contact layer 61 is formed to cover a predetermined area of the second semiconductor layer 25, and not the entire surface of the second semiconductor layer 25. In one example, a metal layer is formed on the entire surface of the second semiconductor layer 25, and is then patterned into a predetermined shape by using a photolithography method to form the contact layer 61.

The cap layer 63 is selectively formed on the second semiconductor layer 25, and covers the contact layer 61. The cap layer 63 may include a silver layer in contact with the contact layer 61. In addition, the cap layer 63 may have a laminated layer structure sequentially including platinum (Pt), titanium (Ti), and gold (Au) in layers from the contact layer 61 side. Silver and platinum have high reflectance with respect to the light radiated from the light emitting layer 23.

As illustrated in FIG. 2B, the third metal layer 50 and a metal layer 40a, which is a precursor to the second metal layer 40, are formed on the second semiconductor layer 25. The third metal layer 50 covers the surface of the second semiconductor layer 25 and the first electrode 60. The metal layer 40a is provided on the third metal layer 50.

The third metal layer 50 may include at least one of titanium (Ti), titanium nitride (TiN), platinum (Pt), and nickel (Ni), and is formed by using a spattering method. The metal layer 40a may contain a solder material such as nickel-tin (NiSn) or gold-tin (AuSn), and is formed by using a vacuum deposition method.

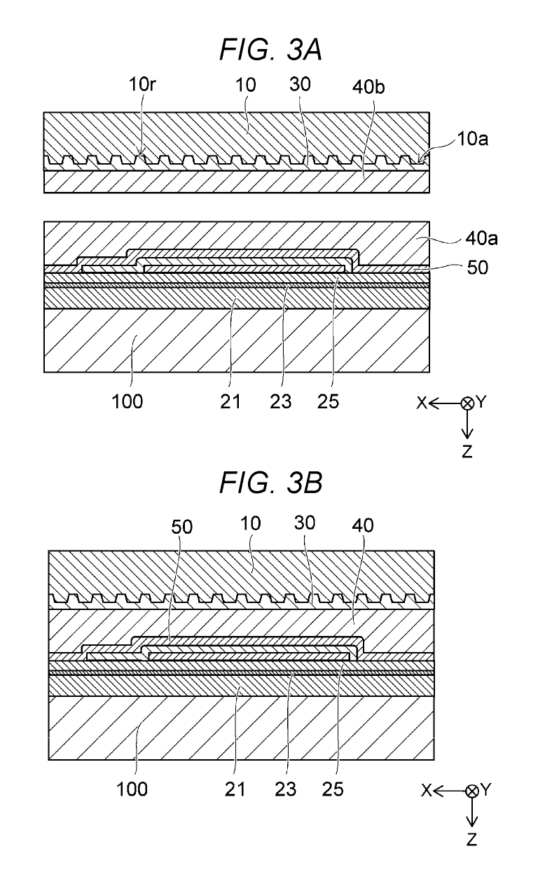

As illustrated in FIG. 3A, the substrate 10 and the substrate 100 are arranged so as to face each other.

The substrate 10 includes a recessed portion 10r on the surface 10a thereof. The recessed portion 10r may be formed by selectively etching the surface 10a. For example, a resist mask which is formed by using the photolithography method may be used to perform the etching. Preferably, the recessed portion 10r is formed in such a manner that an average depth thereof is in a range of from 0.01 μm to 2 μm. More preferably, the recessed portion 10r is formed in such a manner that the average depth thereof is in a range of from 0.01 μm to 1 μm.

In addition, the first metal layer 30 is formed on the surface 10a, and a metal layer 40b, which is a precursor to the second metal layer 40, is formed on the first metal layer 30. The first metal layer 30 may include at least one of Ti, TiN, Pt, and Ni. The first metal layer 30 is formed so as to be embedded into the recessed portion 10r by using, for example, the spattering method.

The first metal layer 30 covers the surface 10a and the recessed portion 10r of the substrate 10, and the metal layer 40b is formed so as to cover the first metal layer 30. The metal layer 40b includes, for example, a solder material such as NiSn or AuSn, and is formed by using the vacuum deposition method. The substrates 10 and 100 are arranged such that the metal layers 40a and 40b are facing each other.

As illustrated in FIG. 3B, the substrate 10 and the substrate 100 are bonded to each other. For example, a temperature is increased to be higher than a melting point of the solder material in a state where the metal layer 40a and the metal layer 40b come into contact with each other. Owing to this configuration, the metal layers 40a and 40b are molten and merge to form the second metal layer 40.

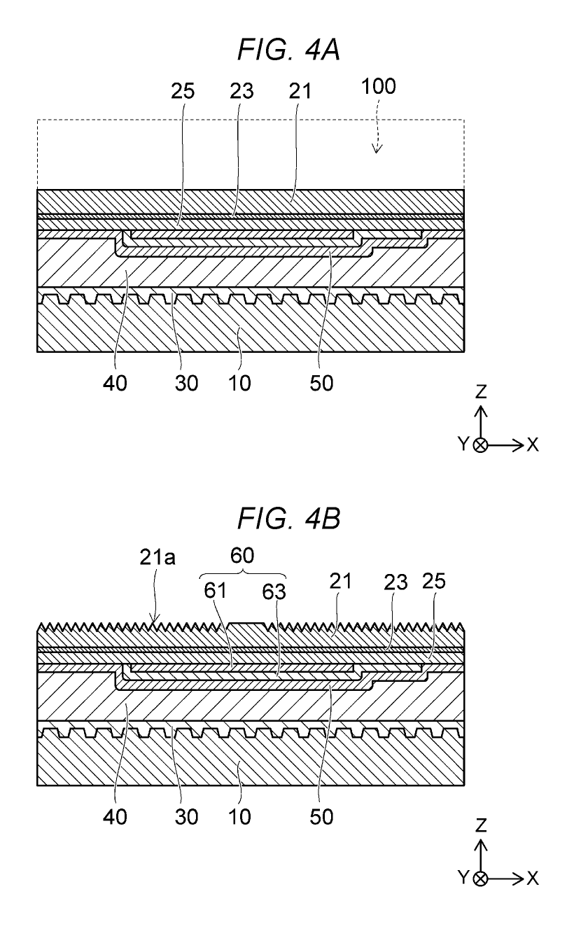

As illustrated in FIG. 4A, the substrate 100 is removed from the surface of the first semiconductor layer 21. The substrate 100 is thinned by being ground and then removed by using a wet etching method. Note that FIG. 4A is a sectional view obtained by turning FIG. 3B upside down (refer to X-, Y-, and Z-axes in FIG. 4A).

As illustrated in FIG. 4B, a surface 21a of the first semiconductor layer 21 is roughened. For example, wet etching may be performed on the first semiconductor layer 21 by using an alkali solution. In the etching process, an etchant may be used that has an etching rate dependent on crystallinity of the surface being etched. Owing to this configuration, it is possible to expose the crystal surface of which the etching rate is slower than others to the surface 21a, so that more crystalline areas are etched slowly and less crystalline areas are etched more quickly. As a result, irregularities are formed on the surface 21a of the first semiconductor layer 21, and the surface 21a is roughened.

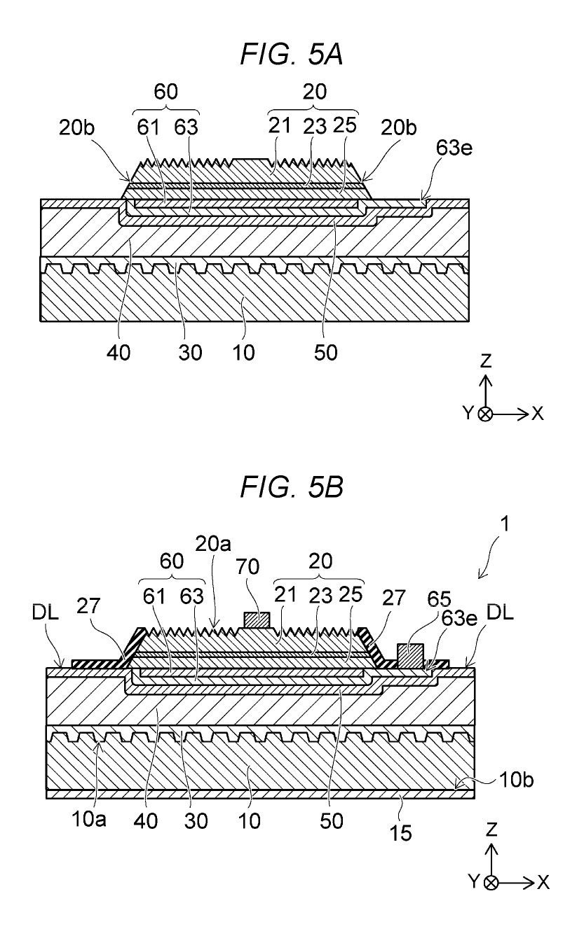

As illustrated in FIG. 5A, the light emitting body 20 is formed by selectively removing the first semiconductor layer 21, the light emitting layer 23, and the second semiconductor layer 25. It is possible to perform, for example, the wet etching on the light emitting body 20 by using a hot phosphoric acid. The extending portion 63e of the cap layer 63 and the third metal layer 50 are exposed in the vicinity of the light emitting body 20.

As illustrated in FIG. 5B, the passivation film 27, the bonding pad 65, and the second electrode 70 are formed. For example, a silicon oxide film may be formed by using a plasma CVD method to cover the light emitting body 20, the third metal layer 50, and the extending portion 63e. Then, the silicon oxide film can be selectively removed and an opening formed on the top surface 20a of the light emitting body 20 and the extending portion 63e. In addition, the dicing line DL is formed.

Sequentially, the bonding pad 65 and the second electrode 70 are formed. The bonding pad 65 is formed on the extending portion 63e. The second electrode 70 is selectively formed on the light emitting body 20, and comes into contact with the top surface 20a. An aluminum layer, which may be formed by a vacuum deposition method, can be used to form the bonding pad 65 and the second electrode 70. Thus, it is possible to form the bonding pad 65 and the second electrode 70 at the same time. Further, the semiconductor light emitting device 1 is finished by forming the fourth metal layer 15 on the rear surface of the substrate 10.

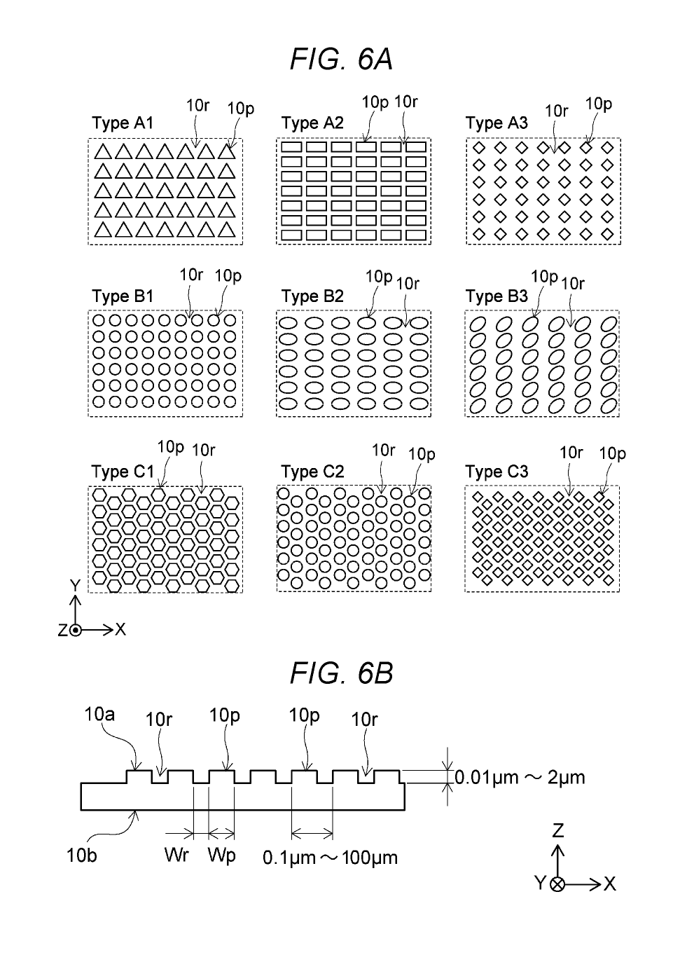

FIGS. 6A and 6B are schematic diagrams illustrating the surface of the substrate 10 according to the first embodiment. FIG. 6A is a plan view illustrating the top surface of the substrate 10, and FIG. 6B is a sectional view of the substrate 10.

As illustrated in FIG. 6A, a plurality of projections 10p are provided on the surface of the substrate 10. The recessed portion 10r is between the projections 10p. The projection 10p can be formed into various shapes in the surface 10a of the substrate 10. For example, as shown in types A1 to A3, the projection 10p may be formed into a triangular, rectangular, or square shape. In addition, as shown in types B1 to B3, the projection 10p may be formed into a circular, oval, or elliptical shape. Further, as shown in types C1 to C3, the projections 10p may be arranged in a staggered disposition.

As illustrated in FIG. 6B, the height of the projection 10p is in a range of from 0.01 μm to 2 μm. In other words, the average depth of the recessed portion 10r is in a range of from 0.01 μm to 2 μm. In addition, for example, a period of the arrangement of the projections 10p in the X-direction may be in a range of from 0.1 μm to 100 μm. In addition, it is preferable that a width Wp of the projection 10p in the X-direction is greater than a width Wr of the recessed portion 10r in the X-direction.

In the embodiment, the recessed portion 10r is formed on the surface 10a of the substrate 10, and the first metal layer 30 is formed so as to be embedded into the recessed portion 10r. Owing to this configuration, a stress generated between the substrate 10 and the first metal layer 30 is released, and thus it is possible to improve adhesive properties.

For example, a metal silicide may be formed at an interface between a silicon substrate and a metal layer which is formed thereon, but additional stress is generated between the silicon substrate and the metal layer by forming the metal silicide. In contrast, in the embodiments described herein, metal silicide is usually not formed between the substrate 10 and the first metal layer 30. Therefore, it is possible to improve the adhesive properties between the substrate 10 and the first metal layer 30 without generating the stress caused by the metal silicide. It is also possible to reduce the manufacturing cost by omitting the metal silicide.

### Second Embodiment

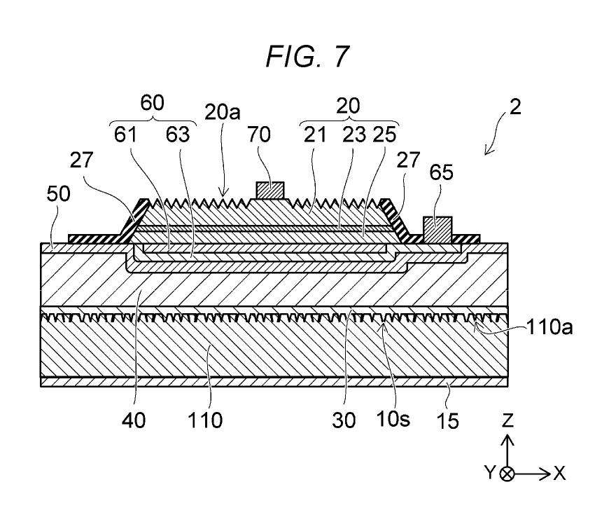

FIG. 7 is a sectional view schematically illustrating semiconductor light emitting device 2 according to the second embodiment. As illustrated in FIG. 7, the semiconductor light emitting device 2 includes the light emitting body 20 and a substrate 110. The light emitting body 20 is provided on the substrate 110 via the metal layers 30, 40, and 50.

The substrate 110 includes a roughened surface 110a. The surface 110a includes a plurality of recessed portions 10s. The depth of the recessed portions 10s is, for example, in a range of from 0.01 μm to 2 μm. The first metal layer 30 is formed on a surface 110a, and is embedded into the recessed portions 10s.

The substrate 110 includes, for example, a surface as cut out from an ingot. In addition, the substrate 110 includes a polished surface such as a surface polished using particulates made of aluminum oxide as polish or abrasive, for example, the particulates having an average particle diameter of 16 μm.

In the embodiment of FIG. 7, the first metal layer 30 is formed on the substrate 110, and is embedded into the recessed portion 10s. Owing to this configuration, it is possible to release the stress generated between the first metal layer 30 and the substrate 110 and to improve adhesive properties. In addition, it is also possible to reduce the manufacturing cost by using a substrate on which mirror finishing is not performed.

In addition, in the embodiment of FIG. 7, the term “nitride semiconductor” includes group III-V compound semiconductors represented by a composition formula of BₓIn_{y}Al_{z}Ga_{1-x-y-z}N (0≦x≦1, 0≦y≦1, 0≦z≦1, 0≦x+y+z≦1). Further, the term “nitride semiconductor” includes compounds having, as a group V element, mixed crystals containing phosphorus (P) or arsenic (As) in addition to N (nitrogen). In addition to the aforementioned composition, the term. “nitride semiconductor” also includes materials with various elements added to control various physical properties such as conductivity type, and various elements that are unintentionally included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light emitting device, comprising:
a substrate that has a surface in which a recessed portion is formed;
a light emitting body on the surface of the substrate and including a first semiconductor layer of a first conductivity type, a second semiconductor layer of a second conductivity type, and a light emitting layer between the first semiconductor layer and the second semiconductor layer; and
a first metal layer between the light emitting body and the surface of the substrate and contacting an inner surface of the recessed portion.

2. The device according to claim 1, wherein an average depth of the recessed portion is in a range of from 0.01 μm to 2 μm.

3. The device according to claim 2, wherein the first semiconductor layer has a roughened surface, and an electrode is formed thereon.

4. The device according to claim 2, wherein the recessed portion includes a plurality of projections having a period of 0.1 μm to 100 μm.

5. The device according to claim 1, further comprising:
a second metal layer including a material having a melting point which is lower than a melting point of a material of the first metal layer, wherein the second metal layer is between the first metal layer and the light emitting body.

6. The device of claim 5, wherein the first metal layer includes a barrier metal and the second metal layer includes a bonding metal.

7. The device according to claim 1, further comprising:
an electrode between the first metal layer and the light emitting body and contacting the first semiconductor layer or the second semiconductor layer, the electrode containing a material that reflects light emitted by the light emitting layer.

8. A semiconductor light emitting device, comprising:
a substrate having a roughened surface;
a light emitting body on the roughened surface of the substrate and including a first semiconductor layer of a first conductivity type, a second semiconductor layer of a second conductivity type, and a light emitting layer between the first semiconductor layer and the second semiconductor layer; and
a metal layer covering at least a portion of the roughened surface between the light emitting body and the substrate, and contacting the roughened surface.

9. The device of claim 8, wherein the roughened surface has a plurality of recessed portions with an average depth of 0.01 μm to 2 μm.

10. The device according to claim 9, wherein metal layer is embedded in the recessed portions.

11. The device of claim 8, further comprising:
a second metal layer including a material having a melting point which is lower than a melting point of a material of the first metal layer, wherein the second metal layer is between the first metal layer and the light emitting body.

12. The device of claim 11, wherein the first metal layer includes a barrier metal and the second metal layer includes a bonding metal.

13. The device according to claim 8, further comprising:
an electrode between the first metal layer and the light emitting body and contacting the first semiconductor layer or the second semiconductor layer, and the electrode containing a material that reflects light emitted from the light emitting layer.

14. The device according to claim 8, wherein the first semiconductor layer has a roughened surface, and an electrode is formed thereon.

15. A semiconductor light emitting device, comprising:
a substrate that has a surface in which a recessed portion is formed;
a light emitting body on the surface of the substrate, and including a first semiconductor layer of a first conductivity type, a second semiconductor layer of a second conductivity type, and a light emitting layer between the first semiconductor layer and the second semiconductor layer;
a first metal layer between the light emitting body and the surface of the substrate and contacting an inner surface of the recessed portion; and
a second metal layer between the first metal layer and the light emitting body.

16. The device of claim 15, wherein the first metal layer includes a barrier metal and the second metal layer includes a bonding metal.

17. The device according to claim 16, wherein the first semiconductor layer has a roughened surface, and an electrode is formed thereon.

18. The device according to claim 16, wherein the recessed portion includes a plurality of projections having a period of 0.1 μm to 100 μm.

19. The device of claim 15, wherein an average depth of the recessed portion is in a range of from 0.01 μm to 2 μm.

20. The device of claim 15, further comprising:
an electrode between the first metal layer and the light emitting body and contacting the first semiconductor layer or the second semiconductor layer, the electrode containing a material that reflects light emitted from the light emitting layer.
